(19) United States
(12) Patent Application Publication
(10) Pub. No.: US 2024/0429323 A1
(43) Pub. Date: Dec. 26, 2024

(54) LOW REVERSE LEAKAGE CURRENT POWER SCHOTTKY DIODES HAVING REDUCED CURRENT CROWDING AT THE LOWER BLOCKING JUNCTION CORNERS

(71) Applicant: Wolfspeed, Inc., Durham, NC (US)

(72) Inventors: Jae-Hyung Park, Apex, NC (US); In-Hwan Ji, Apex, NC (US); Daniel J. Lichtenwalner, Raleigh, NC (US); Edward Robert Van Brunt, Cary, NC (US)

(21) Appl. No.: 18/340,418

(22) Filed: Jun. 23, 2023

(51) Int. Cl. H01L 29/872; H01L 29/16; H01L 29/36

(52) U.S. Cl. CPC H01L 29/872; H01L 29/1608; H01L 29/36

(57) ABSTRACT

A Schottky diode includes a semiconductor layer structure that is interposed between first and second contacts. The semiconductor layer structure comprises a current spreading layer having a first conductivity type, a drift region between the second contact and the current spreading layer, the drift region having the first conductivity type, and a first blocking junction having a second conductivity type that is opposite the first conductivity type, the first blocking junction extending downwardly from an upper surface of the semiconductor layer structure. The current spreading layer has a first conductivity type dopant concentration that is at least 1.5 times greater than a first conductivity type dopant concentration of the drift region and the current spreading layer vertically overlaps at least a portion of a lower half of the first blocking junction.

### FIELD OF THE INVENTION

The present invention relates to power semiconductor devices and, more particularly, to power Schottky diodes.

### BACKGROUND

Power semiconductor devices are used to carry large currents and support high voltages. Power semiconductor devices are typically fabricated from wide band-gap semiconductor materials such as, for example, silicon carbide or gallium nitride based semiconductor materials. Metal contact layers are formed on the semiconductor materials that act as terminals for the device. One widely used power semiconductor device is the Schottky diode. Schottky diodes are two-terminal devices that conduct current between the two terminals when the diode is in its on-state, and which block current flow (even in the presence of large voltages) in their off or “reverse-blocking” state. Two well-known types of Schottky diodes are the Junction Barrier Schottky (“JBS”) diode and the Merged PiN Schottky (“MPS”) diode.

Power Schottky diodes typically have a vertical structure where the anode contact is formed on a first major surface (e.g., the top surface) of a semiconductor layer structure, and the cathode contact is formed on the other major surface (e.g., the bottom surface). Herein, the term “semiconductor layer structure” refers to a structure that includes one or more semiconductor layers such as semiconductor substrates and/or semiconductor epitaxial layers. For example, a conventional silicon carbide power Schottky diode typically has a silicon carbide substrate having a first conductivity type (e.g., an n-type substrate), on which an epitaxial layer structure that comprises one or more first conductivity type (e.g., n-type) epitaxial layers is formed. The epitaxial layers may be formed, for example, by epitaxial growth. Blocking junctions that have a second (different) conductivity type (e.g., p-type) are formed in an upper portion of the epitaxial layer structure. The epitaxial layer structure functions as a drift region of the device, and the blocking junctions define conductive regions through which current flows during on-state operation.

Typically, power Schottky diodes are formed through wafer processing. In particular, a relatively large semiconductor wafer is provided and semiconductor, insulating and/or metal layers are formed on the semiconductor wafer via various wafer-processing steps to form a large number of power Schottky diodes on the wafer. Each power Schottky diode on the wafer may have a “unit cell” structure in which a large number of individual diodes are electrically connected in parallel so that together they function as a single power Schottky diode. The drift region of each Schottky diode includes an “active region” in which the individual unit cell diodes are formed and an edge termination structure that surrounds the active region. The active region acts as a main junction for blocking voltage in the reverse bias direction and providing current flow in the forward bias direction. The edge termination structure may help reduce undesired electric field crowding effects that may occur at the edges of the active region. Each individual power Schottky diode that is formed on a wafer will have active region that has a unit cell structure and its own edge termination structure. After the wafer-level processing is completed, the processed semiconductor wafer is diced (i.e., cut) to singulate the processed wafer into the individual power Schottky diodes. The portion of the wafer included in each individually singulated device is called the substrate.

A power Schottky diode is designed to block (in the reverse blocking state) or pass (in the forward operating state) large voltages and/or currents. For example, in the reverse blocking state, a power Schottky diode may be designed to sustain hundreds or thousands of volts of electric potential that are applied to the cathode contact of the power Schottky diode. The voltage applied to the cathode is referred to as the reverse bias voltage. As the applied reverse bias voltage approaches or passes the voltage level that the device is designed to block (this voltage level is called the reverse breakdown voltage level), non-trivial levels of reverse leakage current may begin to flow through the power Schottky diode. As the reverse bias voltage is increased further, the reverse leakage current may increase rapidly, and the power Schottky diode will enter reverse breakdown and no longer block the reverse bias voltage. Current leakage can also occur for other reasons, such as electric field crowding at the edges of the active region and/or failure of an edge termination and/or the primary junction of the device. If the reverse bias voltage on the power Schottky diode is increased past the reverse breakdown voltage to a critical level, the increasing electric field may result in an uncontrollable and undesirable runaway generation of charge carriers within the power Schottky diode, leading to a condition known as avalanche breakdown that may damage or destroy the device.

For a vertical power Schottky diode, the reverse blocking voltage rating is typically determined by the thickness and the doping concentration of the drift region. The reverse blocking voltage rating of the device may be increased by reducing the doping concentration (and hence the conductivity) of the drift region and/or by increasing the thickness of the drift region. During the design phase, a desired reverse blocking voltage rating is selected, and then the thickness and doping of the drift region may be chosen based on the selected reverse blocking voltage rating. Since the drift region acts as the current path for the device in the forward “on” state, decreasing the doping concentration and/or increasing the thickness of the drift region may result in a higher on-state resistance for the device. Thus, there is an inherent tradeoff between the on-state resistance (and hence the forward voltage that will turn the device on) and the reverse blocking voltage of a power Schottky diode.

### SUMMARY

Pursuant to some embodiments of the present invention, Schottky diodes are provided that comprise a first contact, a second contact and a semiconductor layer structure between the first contact and the second contact. The semiconductor layer structure comprises a current spreading layer having a first conductivity type, a drift region between the second contact and the current spreading layer, the drift region having the first conductivity type, and a first blocking junction having a second conductivity type that is opposite the first conductivity type, the first blocking junction extending downwardly from an upper surface of the semiconductor layer structure. The current spreading layer has a first conductivity type dopant concentration that is at least 1.5 times greater than a first conductivity type dopant concentration of the drift region, and the current spreading layer vertically overlaps at least a portion of a lower half of the first blocking junction.

In some embodiments, at least a portion of the first contact is a Schottky contact.

In some embodiments, the Schottky diode may further comprise a second blocking junction that is doped with dopants having the second conductivity type, the second blocking junction extending downwardly from the upper surface of the semiconductor layer structure, where the first and second blocking junctions extend to a depth of between 1.0 and 2.0 microns into the semiconductor layer structure.

In some embodiments, a conductive region is defined between the first and second blocking junctions, the conductive region having the first conductivity type.

In some embodiments, the first and second blocking junctions are spaced apart from each other by less than 1.0 micron.

In some embodiments, a maximum width of the first blocking junction is less than 1.0 microns.

In some embodiments, the first blocking junction is a channel implanted blocking junction.

In some embodiments, the current spreading layer extends farther downwardly into the semiconductor layer structure than does the first blocking junction.

In some embodiments, a substrate is interposed between the drift region and the second contact.

In some embodiments, the current spreading layer has a first conductivity type dopant concentration that is at least twice the first conductivity type dopant concentration of the drift region.

In some embodiments, the Schottky diode has a reverse voltage blocking rating of at least 650 Volts.

In some embodiments, a bottom of the current spreading layer extends at least as deep into the semiconductor layer structure as a bottom of the first blocking junction, and a doping concentration of the current spreading layer at a depth into the semiconductor layer structure that is the same depth as the bottom of the first blocking junction is at least 1×10¹⁷/cm³.

In some embodiments, at least a first portion of the current spreading layer has a graded doping concentration of first conductivity type dopants, where in the first portion the doping concentration of first conductivity type dopants increases with increasing depth into the semiconductor layer structure.

In some embodiments, the maximum doping concentration of the current spreading layer is at a depth from the upper surface of the semiconductor layer structure that is within 0.2 microns of a depth of a bottom of the first blocking junction.

In some embodiments, the current spreading layer is a buried current spreading layer and the drift region is a lower drift region, the semiconductor layer structure further comprising an upper drift region that is between the current spreading layer and the first contact.

In some embodiments, only the current spreading layer is interposed between the first and second blocking junctions.

In some embodiments, the current spreading layer fills a first portion of the area between the first and second blocking junctions and the drift region fills a second portion of the area between the first and second blocking junctions.

Pursuant to further embodiments of the present invention, Schottky diodes are provided that comprise a first contact that has at least a first portion that is a Schottky contact, a second contact, and a semiconductor layer structure between the first contact and the second contact. The semiconductor layer structure comprises a drift region having a first conductivity type, a current spreading layer between at least a portion of the drift region and the first contact, the current spreading layer having the first conductivity type, where a first conductivity type dopant concentration of the current spreading layer is higher than the first conductivity type dopant concentration of the drift region, and a first blocking junction adjacent the first contact, the first blocking junction having a second conductivity type that is opposite the first conductivity type. A first portion of the current spreading layer has a graded dopant concentration that increases with increasing distance from the first contact.

In some embodiments, the current spreading layer further comprises a second portion that has a graded dopant concentration that decreases with increasing distance from the first contact.

In some embodiments, the current spreading layer further includes a second portion that has a substantially constant dopant concentration with increasing distance from the first contact.

In some embodiments, the semiconductor layer structure further comprising a second blocking junction adjacent the first contact that is doped with dopants having the second conductivity type, where the first and second blocking junctions extend to a depth of between 1.0 and 2.0 microns into the semiconductor layer structure from the first contact.

In some embodiments, the first and second blocking junctions are spaced apart from each other by less than 1.0 micron.

In some embodiments, a maximum width of the first blocking junction is less than 1.0 microns.

In some embodiments, the first blocking junction is a channel implanted blocking junction.

In some embodiments, a minimum distance between the current spreading layer and the second contact is less than a minimum distance between the first blocking junction and the second contact.

In some embodiments, the current spreading layer has a first conductivity type dopant concentration that is at least 1.5 times greater than a first conductivity type dopant concentration of the drift region.

In some embodiments, the current spreading layer is a buried current spreading layer and the drift region is a lower drift region, the semiconductor layer structure comprises an upper drift region that is between the current spreading layer and the first contact.

Pursuant to still other embodiments of the present invention, Schottky diodes are provided that comprise a semiconductor layer structure that comprises a lower drift region having a first conductivity type, an upper drift region having the first conductivity type, a current spreading layer having the first conductivity type between the lower drift region and the upper drift region, where a first conductivity type dopant concentration of the current spreading layer is higher than a first conductivity type dopant concentration of the lower drift region and is higher than a first conductivity type dopant concentration of the upper drift region, a first blocking junction having a second conductivity type that is opposite the first conductivity type, and a second blocking junction having the second conductivity type. The first and second blocking junctions define a conductive region therebetween.

In some embodiments, the Schottky diode further comprises a first contact and a second contact, and the upper drift region is between the first contact and the current spreading layer, the lower drift region is between the second contact and the current spreading layer, and at least a portion of the first contact is a Schottky contact.

In some embodiments, the current spreading layer has a first conductivity type dopant concentration that is at least 1.5 times greater than a first conductivity type dopant concentration of the lower drift region and at least 1.5 times greater than a first conductivity type dopant concentration of the upper drift region.

In some embodiments, the first contact is adjacent top surfaces of the first and second blocking junctions and bottom surfaces of the first and second blocking junctions are between 1.0 and 2.0 microns from an upper surface of the semiconductor layer structure.

In some embodiments, a bottom surface of the current spreading layer is farther from the first contact than are bottom surfaces of the first and second blocking junctions.

In some embodiments, the first and second blocking junctions are spaced apart from each other by less than 1.0 microns.

In some embodiments, the first and second blocking junctions are channel implanted blocking junctions.

Pursuant to additional embodiments of the present invention, Schottky diodes are provided that comprise a first contact, a second contact, and a semiconductor layer structure between the first contact and the second contact. The semiconductor layer structure comprises a current spreading layer having a first conductivity type, a drift region having the first conductivity type between the second contact and the current spreading layer, where a doping concentration of first conductivity type dopants in the current spreading layer exceeds a doping concentration of first conductivity type dopants in the drift region, and a first blocking junction having a second conductivity type that is opposite the first conductivity type, the first blocking junction extending downwardly from an upper surface of the semiconductor layer structure. A bottom surface of the first blocking junction is at a first depth within the semiconductor layer structure, and a doping concentration of the current spreading layer at the first depth exceeds a doping concentration of the drift region by at least a factor of 1.75.

In some embodiments, at least a portion of the first contact is a Schottky contact.

In some embodiments, the Schottky diode further comprises a second blocking junction that is doped with dopants having the second conductivity type, the second blocking junction extensions downwardly from the upper surface of the semiconductor layer structure, where the first and second blocking junctions extend to a depth of between 1.2 and 2.0 microns into the semiconductor layer structure.

In some embodiments, the first and second blocking junctions are spaced apart from each other by less than 1.0 micron.

In some embodiments, the first blocking junction is a channel implanted blocking junction.

In some embodiments, at least a portion of the current spreading layer has a graded doping concentration of first conductivity type dopants where the first conductivity type dopant increases with increasing depth into the semiconductor layer structure.

In some embodiments, the current spreading layer is a buried current spreading layer and the drift region is a lower drift region, the semiconductor further comprises an upper drift region that is between the current spreading layer and the first contact.

Pursuant to yet additional embodiments of the present invention, Schottky diodes are provided that comprise a first contact, a second contact, a drift region having a first conductivity type, and a first blocking junction and a second blocking junction adjacent the first blocking junction that each extend downwardly into the drift region, the first and second blocking junctions having a second conductivity type that is opposite the first conductivity type and defining a conductive region having the first conductivity type therebetween. The current spreading layer has a first conductivity type dopant concentration that is at least 1.5 times greater than a first conductivity type dopant concentration of the drift region, and the first and second blocking junctions extend to a depth of between 1.2 and 2.0 microns into the semiconductor layer structure and the conductive region has a minimum width that is less between 0.1 and 1.0 microns.

In some embodiments, at least a portion of the first contact is a Schottky contact.

In some embodiments, a maximum width of the first blocking junction is less than 1.0 microns.

In some embodiments, the first blocking junction is a channel implanted blocking junction.

In some embodiments, the current spreading layer extends farther downwardly into the semiconductor layer structure than does the first blocking junction.

In some embodiments, the current spreading layer has a first conductivity type dopant concentration that is at least twice the first conductivity type dopant concentration of the drift region.

In some embodiments, at least a portion of the current spreading layer has a graded doping concentration of first conductivity type dopants, where the doping concentration of first conductivity type dopants increases with increasing depth into the semiconductor layer structure.

In some embodiments, the maximum doping concentration of the current spreading layer is at a depth from an upper surface of the semiconductor layer structure that is within 0.2 microns of a depth of a bottom of the first blocking junction.

In some embodiments, the current spreading layer the semiconductor layer structure further comprising a buried current spreading layer and the drift region is a lower drift region, an upper drift region that is between the current spreading layer and the first contact.

Pursuant to still other embodiments of the present invention, Schottky diodes are provided that comprise a first contact, a second contact, and a semiconductor layer structure between the first contact and the second contact. The semiconductor layer structure comprises a drift region having the first conductivity type and a channel implanted first blocking junction having a second conductivity type that is opposite the first conductivity type, the first blocking junction extending downwardly from an upper surface of the semiconductor layer structure. A bottom of the channel implanted first blocking junction is at a first depth within the semiconductor layer structure that is less than 1.75 microns.

In some embodiments, an average width of an upper half of the channel implanted first blocking junction exceeds an average width of a lower half of the channel implanted first blocking junction.

In some embodiments, the Schottky diode further comprises a second blocking junction that is doped with dopants having the second conductivity type and that extends downwardly from the upper surface of the semiconductor layer structure, where the first and second blocking junctions each extend to a depth of between 1.0 and 2.0 microns into the semiconductor layer structure.

In some embodiments, a conductive region is defined between the first and second blocking junctions, the conductive region having the first conductivity type.

In some embodiments, the first and second blocking junctions are spaced apart from each other by less than 1.0 micron.

In some embodiments, a maximum width of the first blocking junction is less than 1.0 microns.

In some embodiments, the current spreading layer extends farther downwardly into the semiconductor layer structure than does the first blocking junction.

In some embodiments, at least a portion of the current spreading layer has a graded doping concentration of first conductivity type dopants, where the doping concentration of first conductivity type dopants increases with increasing depth into the semiconductor layer structure.

In some embodiments, the maximum doping concentration of the current spreading layer is at a depth from the upper surface of the semiconductor layer structure that is within 0.2 microns of a depth of the bottom of the first blocking junction.

In some embodiments, the current spreading layer is a buried current spreading layer and the drift region is a lower drift region, and the semiconductor layer structure comprises an upper drift region that is between the current spreading layer and the first contact.

In some embodiments, the current spreading layer has a first conductivity type dopant concentration that is between 1.5 times and 3.0 times greater than the first conductivity type dopant concentration of the drift region.

In some embodiments, the doping concentration of the current spreading layer at the first depth exceeds a doping concentration of the drift region by no more than a factor of 3.0.

### BRIEF DESCRIPTION OF THE DRAWINGS

FIG. 1A is a schematic plan view of a power Schottky diode according to embodiments of the present invention with the top-side metallization omitted.

FIG. 1B is a schematic cross-sectional view taken along line 1B-1B of FIG. 1A.

FIG. 1C is a graph that illustrates the doping concentration of the blocking junctions as a function of depth within the semiconductor layer structure for the power Schottky diode of FIGS. 1A-1B.

FIG. 2 is a schematic diagram illustrating the relative locations of various crystallographic axes in 4H silicon carbide.

FIGS. 3A-3C illustrate the lattice structure of 4H silicon carbide as viewed along the <0001>, <11-23> and <11-20> crystallographic axes, respectively.

FIGS. 4A-4C are schematic cross-sectional diagrams of Schottky diodes having blocking junctions formed using different ion implantation processes.

FIG. 5A is a schematic cross-sectional view of a power Schottky diode according to further embodiments of the present invention.

FIG. 5B is a schematic cross-sectional view of a modified version of the power Schottky diode of FIG. 5A.

FIG. 6 is a schematic cross-sectional view of a power Schottky diode according to additional embodiments of the present invention.

FIG. 7 is a schematic cross-sectional view of a power Schottky diode according to still further embodiments of the present invention.

FIGS. 8A-8E are schematic cross-sectional diagrams that illustrate a method of fabricating a power Schottky diode according to embodiments of the present invention.

FIG. 9 is a graph that compares the reverse leakage current performance of a conventional power Schottky diode to a power Schottky diode according to embodiments of the present invention.

### DETAILED DESCRIPTION

Power Schottky diodes are desired that have a low on-state resistance values as well as the ability to block high voltage levels in the reverse blocking state with low leakage currents. As discussed above, an inherent tradeoff exists between the on-state resistance and the reverse leakage current in a power Schottky diode. Generally speaking, improved (i.e., reduced) on-state resistances results in degraded (i.e., increased) reverse leakage current values for a given reverse bias voltage.

Pursuant to embodiments of the present invention, power Schottky diodes are provided that use a combination of one or more of (1) deeper blocking junctions, (2) the use of channeled ion implantation for forming the blocking junctions, (3) current spreading layers. (4) unconventional current spreading layer designs (e.g., buried current spreading layers or current spreading layers that have increasing doping density with increasing depth) and/or (5) an increased number of smaller, more closely spaced blocking junctions to provide significantly improved performance.

The use of deeper blocking junctions may reduce the intensity of the electric field in the upper portion of the drift region during reverse blocking operation, which reduces the reverse leakage current. The use of a larger number of narrower, more closely spaced blocking junctions may further reduce the intensity of the electric field in the upper portion of the drift region during reverse blocking operation, which again acts to reduce the reverse leakage current. However, each of the above techniques tends to increase the on-resistance.

The increase in the on-state resistance that may result from the deeper blocking junctions and/or the use of a larger number of narrower, more closely spaced blocking junctions may be at least partially offset by forming the blocking junctions using channeled ion implantation techniques. While channeled ion implantation techniques are known in the art, they are typically used in situations in which very deep implants are needed (e.g., implants to depths exceeding 2 microns) or in situations where ion implantation damage needs to be reduced (e.g., when a conductive region of a device is formed by ion implantation). In contrast, according to some embodiments of the present invention, channeled ion implantation techniques may be used to form blocking junctions having, for example, depths of less than 2.0 microns or even less than 1.5 microns. Channeled ion implants are used even though the blocking junctions are at depths that can readily be achieved using standard (non-channeled) ion implantation techniques because the channeled ion implants exhibit less straggle (which refers to the implantation of ions outside a target region for the implanted ions). Since straggle results in opposite conductivity type ions being implanted in the conductive regions of a power Schottky diode, straggle can reduce the effective width of the conductive regions, and hence increase the on-state resistance of the power Schottky diode. Thus, by reducing the amount of straggle as compared to conventional power Schottky diodes, the current flow through the conductive region may be improved. Blocking junctions formed via channeled ion implants may also have improved shapes (e.g., the blocking junctions may be the widest at intermediate depths) which may reduce unwanted current crowding effects that can occur at the lower corners of the blocking junctions that can increase the on-state resistance.

The provision of current spreading layers in the power Schottky diodes according to embodiments of the present invention may reduce the on-state resistance without having a significant impact on the reverse leakage current levels, since the current spreading layers may have limited thicknesses. The current spreading layers may have unique designs (e.g., the use of buried current spreading layers or reverse graded current spreading layers) that act to primarily increase the conductivity of the drift region around the lower corners of the blocking junctions, which can help offset the above-discussed increases in on-resistance. The net result is that power Schottky diodes can be provided that exhibit lower reverse leakage currents with little or no countervailing increase in on-resistance.

Pursuant to some embodiments of the present invention, power Schottky diodes are provided that comprise first and second contacts (e.g., anode and cathode contacts, respectively) and a semiconductor layer structure that is interposed between the first and second contacts. The semiconductor layer structure comprises a current spreading layer having a first conductivity type, a drift region between the second contact and the current spreading layer, the drift region having the first conductivity type, and a first blocking junction having a second conductivity type that is opposite the first conductivity type. The first blocking junction extends downwardly from an upper surface of the semiconductor layer structure. The current spreading layer has a first conductivity type dopant concentration that is at least 1.5 times greater than a first conductivity type dopant concentration of the drift region and the current spreading layer vertically overlaps at least a portion of a lower half of the first blocking junction.

Pursuant to further embodiments of the present invention, Schottky diodes are provided that comprise a first contact (e.g., an anode contact) that has at least a first portion that is a Schottky contact, a second contact, and a semiconductor layer structure that is between the first contact and the second contact. The semiconductor layer structure comprises a drift region having a first conductivity type, a current spreading layer between at least a portion of the drift region and the first contact, the current spreading layer having the first conductivity type, where a first conductivity type dopant concentration of the current spreading layer is higher than the first conductivity type dopant concentration of the drift region, and a first blocking junction adjacent the first contact, the first blocking junction having a second conductivity type that is opposite the first conductivity type. A first portion of the current spreading layer has a graded dopant concentration that increases with increasing distance from the first contact.

Pursuant to additional embodiments of the present invention, Schottky diodes are provided that comprise a semiconductor layer structure comprising a lower drift region having a first conductivity type, an upper drift region having the first conductivity type, a current spreading layer between the lower drift region and the upper drift region and having the first conductivity type, where a first conductivity type dopant concentration of the current spreading layer is higher than a first conductivity type dopant concentration of the lower drift region and is higher than a first conductivity type dopant concentration of the upper drift region. The semiconductor layer structure further comprises a first blocking junction having a second conductivity type that is opposite the first conductivity type, and a second blocking junction having the second conductivity type. The first and second blocking junctions define a conductive region therebetween.

Pursuant to other embodiments of the present invention, Schottky diodes are provided that comprise a first contact, a second contact, and a semiconductor layer structure between the first contact and the second contact. The semiconductor layer structure comprises a current spreading layer having a first conductivity type, a drift region having the first conductivity type between the second contact and the current spreading layer, where a doping concentration of first conductivity type dopants in the current spreading layer exceeds a doping concentration of first conductivity type dopants in the drift region. The semiconductor layer structure further comprises a first blocking junction having a second conductivity type that is opposite the first conductivity type, the first blocking junction extending downwardly from an upper surface of the semiconductor layer structure. A bottom surface of the first blocking junction is at a first depth within the semiconductor layer structure, and a doping concentration of the current spreading layer at the first depth exceeds a doping concentration of the drift region by at least a factor 1.75.

Pursuant to additional embodiments of the present invention, Schottky diodes are provided that comprise a first contact, a second contact, a drift region having a first conductivity type, and first and second blocking junctions that each extend downwardly into the drift region, the first and second blocking junctions having a second conductivity type that is opposite the first conductivity type and defining a conductive region having the first conductivity type therebetween. The current spreading layer has a first conductivity type dopant concentration that is, for example, at least 1.5 times greater (or at least 1.75 times greater) than a first conductivity type dopant concentration of the drift region, and where the first and second blocking junctions extend to, for example, a depth of between 1.2 and 2.0 microns into the semiconductor layer structure and the conductive region has a minimum width that is between 0.5 and 2.0 microns.

Pursuant to yet additional embodiments of the present invention, Schottky diodes are provided that comprise a first contact, a second contact, and a semiconductor layer structure between the first contact and the second contact. The semiconductor layer structure comprises a drift region having the first conductivity type and a channel implanted first blocking junction having a second conductivity type that is opposite the first conductivity type. The first blocking junction extending downwardly from an upper surface of the semiconductor layer structure. A bottom of the channel implanted first blocking junction is at a first depth within the semiconductor layer structure that is less than 1.75 microns.

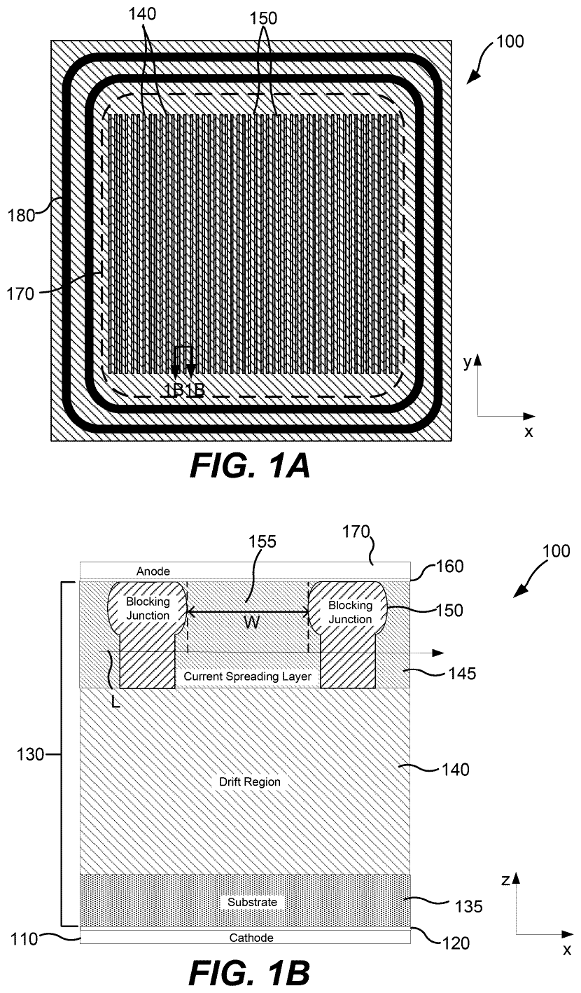

Example embodiments of the present invention will now be described with reference to FIGS. 1A-9. It will be appreciated that features of the different embodiments disclosed herein may be combined in any way to provide many additional embodiments.

FIG. 1A is a simplified schematic plan view of a power Schottky diode 100 according to embodiments of the present invention. In FIG. 1A, the topside metallization of the power Schottky diode 100 has been omitted to illustrate the locations of the blocking junctions and the conductive regions formed therebetween, although a dashed line (labelled 170) is included that shows the location of the periphery of the anode contact 170 of the Schottky diode 100. FIG. 1B is a schematic cross-sectional view of the power Schottky diode 100 taken along line 1B-1B of FIG. 1A.

As shown in FIGS. 1A-1B, the power Schottky diode 100 includes a cathode contact 110, an ohmic contact layer 120, a semiconductor substrate 135, a drift region 140, a current spreading layer 145, blocking junctions 150, conductive regions 155, a Schottky contact 160, and an anode contact 170. The semiconductor substrate 135, the drift region 140, the current spreading layer 145, the blocking junctions 150, and the conductive regions 155 comprise a semiconductor layer structure 130.

The cathode contact 110 may form the bottom layer of the Schottky diode 100. The ohmic contact layer 120 and the semiconductor layer structure 130 are stacked on the cathode contact 110, with the ohmic contact layer 120 between the cathode contact 110 and the semiconductor layer structure 130. The current spreading layer 145 is formed above the drift region 140 or in an upper portion of the drift region 140. The blocking junctions 150 are formed at least partially in the current spreading layer 145 and may extend into portion(s) of the drift region 140. The conductive regions 155 are part of the current spreading layer 145. The Schottky contact 160 is formed on an upper surface of the semiconductor layer structure 130 and the anode contact 170 is formed on the upper surface of the Schottky contact 170.

The cathode contact 110 may comprise a highly conductive metal layer such as a silver layer. In some embodiments, the cathode contact 110 may comprise a multilayer metal structure such as, for example, a Ti/Ni/Ag structure. The ohmic contact layer 120 may comprise a metal that forms an ohmic contact to the semiconductor substrate 135. The illustrated device is a silicon carbide based n-type Schottky diode, so the semiconductor layer structure 130 comprises silicon carbide semiconductor materials and the ohmic contact layer 120 is a metal that forms an ohmic contact to n-type silicon carbide. The semiconductor substrate 135 may be an n-type silicon carbide semiconductor substrate. The n-type silicon carbide semiconductor substrate 135 may comprise, for example, a piece of a 4H silicon carbide semiconductor wafer. The substrate 135 may be heavily doped with n-type impurities (i.e., an n⁺ silicon carbide substrate) such as nitrogen or phosphorous. The doping concentration of n-type dopants in the semiconductor substrate 135 may be, for example, between 1×10¹⁸ atoms/cm³ and 1×10²¹ atoms/cm³. The substrate 135 may be any appropriate thickness. The thickness of the semiconductor substrate 135 shown in FIG. 1B is not to scale to better illustrate the structure of the other layers in the power Schottky diode 100. In some embodiments, the semiconductor substrate 135 may be partially or completely removed prior to formation of the ohmic contact layer 120 and the cathode contact 110.

The drift region 140 may be an n-type silicon carbide drift region 140 that is formed via epitaxial growth on the n-type silicon carbide substrate 135. In some embodiments, the drift region 140 may be doped during growth with n-type dopants to a concentration of, for example, between 1×10¹⁴/cm³ and 2×10¹⁷/cm³. In other embodiments, the drift region 140 may be doped during growth with n-type dopants to a concentration of, for example, between 5×10¹⁵/cm³ and 1×10¹⁷/cm³. The drift region 140 may be uniformly doped in some embodiments.

The current spreading layer 145 may be an n-type silicon carbide region that is formed via epitaxial growth on the n-type silicon carbide drift region 140. The current spreading layer 145 may be doped with n-type dopants to a concentration of, for example, between 1.5×10¹⁴/cm³ and 6×10¹⁷/cm³. In other embodiments, the current spreading layer 145 may be doped with n-type dopants to a concentration of, for example, between 8×10¹⁵/cm³ and 5×10¹⁷/cm³. The current spreading layer 145 may be doped during growth or may be formed by implanting additional n-type dopants into an upper portion of the drift region 140. In some embodiments, the current spreading layer 145 may have an n-type dopant concentration that is at least 1.5 times greater than the n-type dopant concentration of the drift region 140. In example embodiments, the current spreading layer 145 may have an n-type dopant concentration that is between 1.5 times and 4.0 times greater than the n-type dopant concentration of the drift region 140. In other embodiments, the current spreading layer 145 may have an n-type dopant concentration that is between 1.5 times and 3.0 times greater than the n-type dopant concentration of the drift region 140, between 2.0 times and 3.0 times greater than the n-type dopant concentration of the drift region 140, or between 2.0 times and 2.5 times greater than the n-type dopant concentration of the drift region 140. The current spreading layer 145 may be between 1.75 and 2.0 microns thick. However, if deeper blocking junctions are used, the depth of the current spreading layer 145 may be increased well beyond 2.0 microns and even beyond 3 microns or 4 microns. The current spreading layer 145 is uniformly doped in the depicted embodiments.

A series of p-type blocking junctions 150 are formed in the current spreading layer 145. The p-type blocking junctions 150 may also be referred to herein as junction barrier regions. The p-type blocking junctions 150 are typically formed by implanting p-type dopants into selected regions of the current spreading layer 145 and/or the drift region 140. As known to those skilled in the art, ions such as n-type or p-type dopants may be implanted in a semiconductor layer or region by ionizing the desired ion species and accelerating the ions at a predetermined kinetic energy as an ion beam towards the surface of a semiconductor layer in an ion implantation target chamber. Based on the predetermined kinetic energy, the desired ion species may penetrate into the semiconductor layer with a statistical distribution of depths as different ions will penetrate to different depths as they bounce off atoms within the semiconductor crystal structure. Depending upon the desired size and dopant distribution for the implanted region, one or more ion implantation steps may be performed to form the p-type blocking junctions 150, where each ion implantation step may have a different implantation energy and/or dosage level of dopants.

The p-type blocking junctions 150 may be highly doped with p-type dopants to a concentration of, for example, at least 1×10¹⁸/cm³ in some embodiments. In other embodiments, the p-type blocking junctions 150 may be doped with p-type dopants to a concentration of at least 5×10¹⁸/cm³, and in still other embodiments, to a concentration of at least 1×10¹⁹/cm³. The p-type blocking junctions 150 may be deep blocking junctions that extend deeper into the semiconductor layer structure 130 than is the case in most conventional Schottky diodes. In some embodiments, the blocking junctions 150 may extend to a depth of at least 1.2 microns from the upper surface of the semiconductor layer structure 130. In other embodiments, the blocking junctions 150 may extend to a depth of at least 1.5 microns or 1.8 microns from the upper surface of semiconductor layer structure 130. In example embodiments, the blocking junctions 150 may extend to a depth of between 1.0 and 2.0 microns or between 1.2 microns and 1.8 microns. The maximum horizontal (lateral) width of each blocking junction 150 may be, for example, between 0.5 and 1.5 microns.

The bottom surfaces of the blocking junctions 150 may be at a first depth within the semiconductor layer structure 130, and a doping concentration of the current spreading layer 145 at this first depth may exceed a doping concentration of the drift region 140 by at least a factor of 1.5 in some embodiments and at least a factor of 1.75 or 2.0 in other embodiments. In each of these embodiments, the doping concentration of the current spreading layer 145 at the first depth may exceed the doping concentration of the drift region 140 by no more than a factor of 4.0.

Adjacent blocking junctions 150 may be laterally spaced apart from each other at distances of between, for example, 0.5 and 2.0 microns in some embodiments and by or between 0.6 and 1.5 microns in other embodiments. Thus, in some embodiments, adjacent blocking junctions 150 may be laterally spaced apart from each other by less than 1.0 micron. Conductive regions 155 are defined in the portions of the n-type current spreading layer 145 that are between adjacent p-type blocking junctions 150. The conductive regions 155 are part of the current spreading layer 145. The width of each conductive region 155 may correspond to the lateral distance between adjacent blocking junctions 150 (i.e., the conductive regions 155 have widths W of between 0.5 and 2.0 microns). The width of each conductive region 155 typically will not be constant, and the minimum width tends to be the important parameter. In one example embodiment, the minimum widths W of the conductive regions 155 may be between 0.5 and 1.0 microns The p-type blocking junctions 150 may reduce the strength of the electric field that is formed when the Schottky diode 100 is in the reverse blocking state as it helps shield the Schottky contact 160 from the electric field. The conductive regions 155 pass current when the Schottky diode 100 is operating in its forward on-state and block voltage when the Schottky diode 100 is operating in its reverse blocking state.

A Schottky contact 160 may be formed on top of the blocking junction 150 and the conductive regions 155. The Schottky contact 160 may comprise a layer that forms a Schottky junction with the semiconductor layer structure 130 and may comprise, for example, an aluminum layer, a titanium layer or a nickel layer. An anode contact 170 may be formed on the Schottky contact 160 opposite the drift region 140. The anode contact 170 may comprise a highly conductive metal layer such as an aluminum layer.

In FIGS. 1A-1B, each blocking junction 150 and a conductive region 155 adjacent thereto may be considered to be a unit cell of the Schottky diode 100. Thus, the Schottky diode 100 depicted in FIGS. 1A-1B has approximately fifty unit cells. The cross-section of FIG. 1B illustrates approximately two of the unit cells of the Schottky diode 100 (in particular, it illustrates the blocking junctions 150 of two unit cells, the conductive region 155 of one unit cell and portions of the conductive regions 155 of two other units cells).

As shown in FIGS. 1A-1B, the Schottky diode 100 includes a first contact in the form of the Schottky contact 160 (and/or the anode contact 170) and a second contact in the form of the ohmic contact 120 (and/or the cathode contact 110). A semiconductor layer structure 130 is interposed between the first and second contacts 160/170, 110/120. The semiconductor layer structure 130 comprises a current spreading layer 145 having a first conductivity type (here n-type), a drift region 140 between the second contact 110 and the current spreading layer 145, the drift region 140 having the first conductivity type (here n-type), and a first blocking junction 150 having a second conductivity type (here p-type) that is opposite the first conductivity type. The first blocking junction 150 extends downwardly from an upper surface of the semiconductor layer structure 130. The current spreading layer 145 has a first conductivity type dopant concentration that is at least 1.5 times greater than a first conductivity type dopant concentration of the drift region 140 and the current spreading layer 145 vertically overlaps at least a portion of the lower half of the first blocking junction 150. Herein, two regions of a semiconductor layer structure “vertically overlap” if an axis that is parallel to the major plane defined by the upper surface of the semiconductor layer structure (i.e., a laterally extending axis) intersects both regions. An axis L is provided in FIG. 1B that shows how the blocking junctions 150 vertically overlap the lower half of the current spreading layer 145.

As is shown in FIG. 1A, a plurality of guard rings 180 surround the active region of the power Schottky diode 100. The guard rings 180 may comprise p-type trench regions that are formed via ion implantation into the upper surface of the drift region 140. The guard rings 180 may surround the active region of the power Schottky diode 100. The guard rings 180 may, for example, extend into the drift region 140 to a depth that is about the same as the depth of the blocking junctions 150. The guard rings 180 may comprise edge termination structures. Other edge termination structures such as, for example, a junction termination extension may be used in place of the guard rings 180. The guard rings 180 may reduce the above-described electric field crowding (and the resulting increased leakage currents) at the edges of the active region. The guard rings 180 (or other edge termination structure) may spread the electric field out over a greater area, thereby reducing the electric field crowding. While FIG. 1A illustrates a power semiconductor device 100 that uses two guard rings 180 as an edge termination structure, it will be appreciated that more or fewer guard rings 180 may be provided. The edge termination structure may be omitted in some embodiments.

When the power Schottky diode 100 is operated in reverse blocking mode and a large voltage is applied to the cathode contact 110, a strong electric field is formed that extends upwardly from the silicon carbide substrate 135 throughout the drift region 140 and toward and into the conductive regions 155. The deep blocking junctions 150 may reduce the intensity of the electric field in the upper portion of the drift region 140 during reverse blocking operation. As the reverse voltage is increased, the electric fields in the conductive regions 155 will be sufficiently high so that leakage currents may begin to flow, both through the conductive regions 155 and at the edges of the active region (i.e., the regions just within the inner guard ring 180 in FIG. 1A). If the reverse voltage applied to the device is increased past the reverse breakdown voltage to a critical level, the increasing electric field may result in runaway generation of charge carriers within the Schottky diode 100, leading to avalanche breakdown. When avalanche breakdown occurs, the current increases sharply and may become uncontrollable, and an avalanche breakdown event may damage or destroy the Schottky diode 100.

The power Schottky diode 100 uses a combination of several features to provide improved performance as compared to conventional power Schottky diodes. First, the power Schottky diode 100 includes deeper blocking junctions 150 as compared to most Schottky diodes. The deeper blocking junctions 150 may better block electric fields from extending through the conductive regions 155 during reverse blocking operation, thereby reducing the leakage current levels through the device. Second, these deeper blocking junctions 150 are formed using channeled ion implantation, even though they are at depths that can be implanted using standard non-channeled ion implantation techniques. As will be discussed in greater detail below, by forming the blocking junctions 150 using a channeled ion implantation the amount of straggle can be advantageously reduced and/or the shapes of the blocking junctions 150 can be optimized, both of which may improve the on-state performance of the Schottky diode 100 as compared to conventional Schottky diodes. Third, the Schottky diode 100 includes a current spreading layer 145 that has an n-type doping concentration that is, for example, between 1.5 and 4.0 times the n-type doping concentration of the drift region 140. Notably, the current spreading layer 145 extends to the lower portions of the blocking junctions 150 so that the portions of the conductive regions 155 that are adjacent the lower corners of the blocking junctions 150 have an increased doping concentration.

As discussed above, in some embodiments, the p-type blocking junctions 150 of Schottky diode 100 may be formed using a channeled ion implantation process. Channeled ion implantation refers to an ion implantation process in which the ions are implanted along a crystallographic axis of the semiconductor material so that the ions can travel through channels in the semiconductor crystal that are between atoms. Channeled ion implantation techniques are based on a realization that the depth and quality of an ion implantation step in 4H silicon carbide and other high bandgap and/or compound semiconductor materials will be a function of the lattice structure as seen along the longitudinal axis of the ion beam. In particular, there are certain geometrical relationships between the ion beam and the lattice structure of the silicon carbide (or other material) that can provide large channels (i.e., regions where there are no atoms present) that are particularly effective for achieving deep dopant ion implantation depths and more uniform dopant concentration as a function of depth. By implanting ions directly along these channels, implanted regions can be formed in silicon carbide that exhibit good uniformity as a function of depth using lower energy implants. Channeled ion implantation techniques are typically used when very deep implanted regions need to be formed that either cannot be formed using regular ion implantation techniques or in cases where reduced lattice damage is important.

In general, channeling occurs in silicon carbide when the direction of implantation is within about 2° of a crystallographic axis of the silicon carbide crystal and, more particularly when the direction of implantation is within +/−1° of a crystallographic axis. When the direction of implantation is offset by more than +/−1° from each crystallographic axis, the channeling effect is significantly reduced, and when the direction of implantation is offset by more than about 2° from each crystallographic axis of the silicon carbide crystal, the atoms in the crystal lattice may appear to be randomly distributed relative to the direction of implantation.

When ions are implanted into a semiconductor material, the implanted ions tend to scatter when they impact atoms in the crystal lattice of a semiconductor material. When the direction of implantation is oriented at an oblique angle to each of the major axes of the crystal lattice, the atoms in the crystal lattice may appear to have a random distribution relative to the direction of implantation. As a result, the likelihood of collisions between implanted ions and atoms in the crystal lattice may be fairly uniform with increasing depth. If, however, the direction of implantation is along (or very close to) a major axis of the crystal lattice, the atoms in the crystal lattice may “line up” relative to the direction of implantation. When the atoms line up in this fashion as viewed along the longitudinal axis of the ion beam, channels appear in the crystal lattice where no atoms are located. When ions are implanted along these channels, the implanted ions may tend to travel down the channels in the crystal structure. This reduces the likelihood of collisions between the implanted ions and the atoms in the crystal lattice, especially near the surface of the semiconductor layer. As a result, the implant depth of the ion implant for a given implant energy may be greatly increased. As used herein, the term “implant depth” refers to the depth from a surface of the crystal that the ions are implanted into at which the concentration of implanted dopants falls below 1×10¹⁵ cm⁻³.

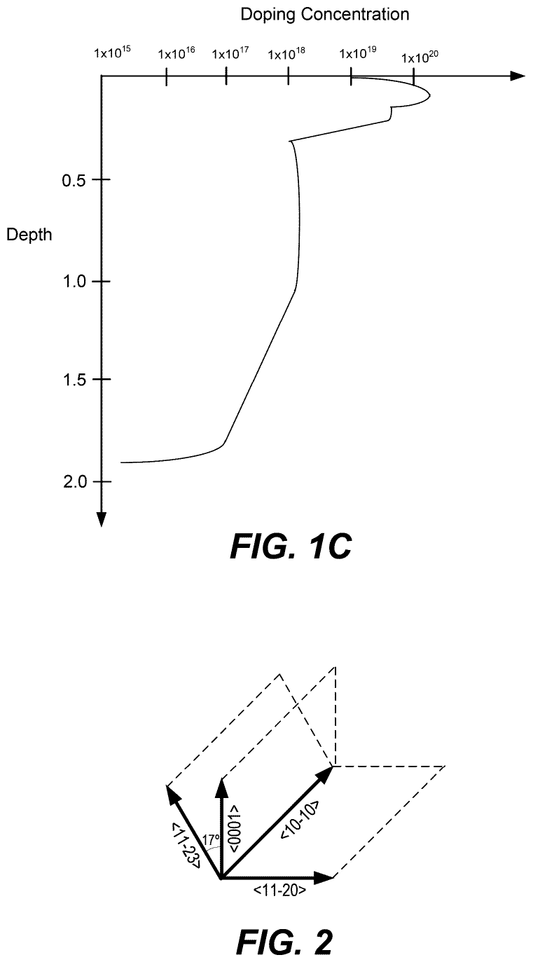

FIG. 2 is a schematic diagram illustrating the relative locations of various crystallographic axes in 4H silicon carbide. As shown in FIG. 2, the <10-10> crystallographic axis is perpendicular to each of the <0001>, <11-20> and <11-23> crystallographic axes. The <11-20> crystallographic axis is perpendicular to the <0001> crystallographic axis, and the <11-23> crystallographic axis is offset by about 17° from the <0001> crystallographic axis in the direction away from the <11-20> crystallographic axis.

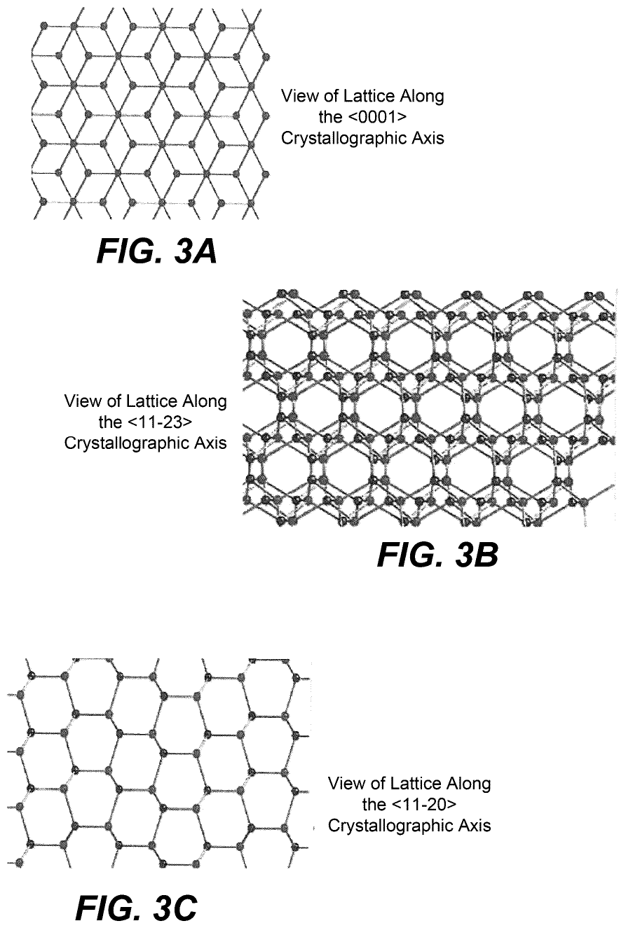

FIGS. 3A-3C illustrate the lattice structure of 4H silicon carbide as seen along the <0001>, <11-23> and <11-20> crystallographic axes, respectively. As shown in FIG. 3A, the density of atoms at the surface (the atoms are shown by the small circles in FIG. 3A) is relatively low, which is a favorable condition for deeper ion implant depths. A plurality of channels are provided between the atoms which allow for channeling of the implanted ions to relatively deeper depths into the semiconductor material. However, the channels themselves are relatively small in cross-sectional area. Relatively speaking, the smaller a channel is in cross-sectional area, the shallower the implant depth. Thus, while ion implantation along the <0001> crystallographic axis will exhibit channeling, the implant depths achievable are still limited.

FIG. 3B illustrates the lattice structure of 4H silicon carbide as viewed along the <11-23> crystallographic axis. The lattice structure will look the same as shown in FIG. 3B when viewed along any of the <−1-123>, <1-213>, <−12-13>, <Feb. 1, 2013> and <−2113> crystallographic axes. Given the hexagonal lattice of 4H silicon carbide, the six crystallographic axes listed above are all offset by 17 degrees from the <0001> crystallographic axis and are spaced apart from each other by 60 degree increments. The vectors that are offset by 17 degrees from the <0001> crystallographic axis form a cone that rotates through 360 degrees. The <11-23>, <−1-123>, <1-213>, <−12-13>, <Feb. 1, 2013> and <−2113> crystallographic axes all extend along this cone, and are separated from each other by 60 degrees. At most rotation angles about this cone, the lattice structure will appear “crowded” with closely-spaced atoms throughout. However, as shown with reference to FIG. 3B, at six different locations that correspond to the <11-23>, <−1-123>, <1-213>, <−12-13>, <Feb. 1, 2013> and <−2113> crystallographic axes, the atoms “line up” so that distinct channels appear in the lattice structure. As can be seen in FIG. 3B, along these six crystallographic axes, the density of atoms at the surface is increased as compared to the example of FIG. 3A, which will typically result in increased scattering of ions. Advantageously, however, the channels that are provided between the atoms have a larger cross-sectional area as compared to the channels in the example of FIG. 3A. This allows for increased implant depths.

As can be seen in FIG. 3C, when 4H silicon carbide is viewed along the <11-20> crystallographic axis, the density of atoms at the surface may be very low, and channels having large cross-sectional areas are provided within the lattice structure. Such a structure may allow for very deep implant depths. Unfortunately, however, the <11-20> crystallographic axis is typically nearly perpendicular to the major faces of a silicon carbide wafer when the wafer is cut in a traditional manner, and hence it may be difficult to provide silicon carbide wafers that have a major face cut along, or at a relatively small tilt from, the <11-20> crystallographic axis.

Conventionally, 4H silicon carbide wafers are cut from boules of bulk 4H silicon carbide material at a small offset angle from the plane defined by the <10-10> and <11-20> crystallographic axes. This offset angle is often referred to as an “off-cut” angle. While the boules are sometimes cut directly along the plane defined by the <10-10> and <11-20> crystallographic axes, higher quality silicon carbide epitaxial layers can typically be grown when the silicon carbide wafers are cut at a small off-cut angle from this plane. Off-cut angles of about 2° to about 8° are common. Thus, for example, if a 4H silicon carbide wafer is cut at a 4° angle from the plane defined by the <10-10> and <11-20> crystallographic axes (tilted toward the <11-23> crystallographic axis) then to implant along the <11-23> crystallographic axis, the ions should be implanted at an implant angle of 13° from the upper surface of the wafer. Similar adjustments to the implant angle (from 17°) are necessary if the ions are to be implanted along one of the other five crystallographic axes that are symmetrically equivalent to the <11-23> crystallographic axis). Herein, the term “implant angle” refers to the angle between the direction of implantation during an ion implantation step and a crystallographic axis of the semiconductor material into which the ions are implanted, such as the c-axis or <0001> axis of a 4H silicon carbide semiconductor layer structure.

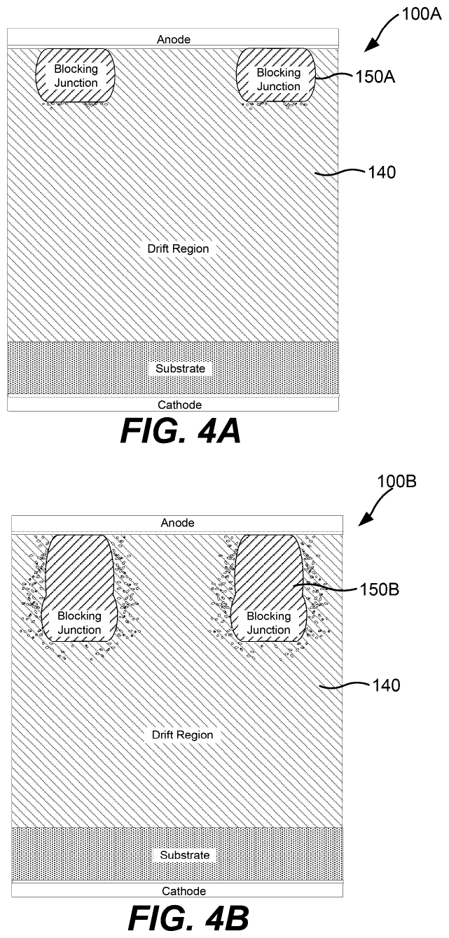

As discussed above, channeled ion implantation is typically used in silicon carbide processing in situations where very deep implants are required into the silicon carbide material, such as implants having depths exceeding 2 microns, or more typically, implants having depths exceeding 2.5 microns or 3.0 microns. Aspects of certain embodiments of the present invention are based on the realization that another advantage of using channeled ion implants is that the amount of straggle that occurs with channeled ion implant may be significantly less as compared to non-channeled ion implants. Additionally, the shape of the implanted regions will differ with respect to channeled versus non-channeled ion implants (assuming that a single implantation step is performed). The shape of blocking junctions in silicon carbide based Schottky diodes that are formed using channeled ion implants may be preferable to the shape of blocking junctions formed using non-channeled ion implants. This can be seen with reference to FIGS. 4A-4C.

In particular, FIG. 4A is a cross-sectional view of a small portion of a 4H silicon carbide based Schottky diode 100A that illustrates a pair of p-type blocking junctions 150A that are formed using conventional ion implantation techniques. The p-type blocking junctions 150A have a conventional implant depth of about 0.6-0.7 microns into the semiconductor layer structure. The p-type blocking junction 150A exhibits relatively low-levels of straggle, since the ion implant is formed using lower implant energies. Moreover, the straggle is predominantly underneath the p-type blocking junction 150A. The implantation of stray p-type ions underneath the p-type blocking junction 150A typically does not have a significant impact on performance.

FIG. 4B is a cross-sectional view of a small portion of a 4H silicon carbide based Schottky diode 100B that illustrates a pair of deep p-type blocking junctions 150B that are formed using conventional ion implantation techniques. The p-type blocking junctions 150B have a significantly deeper implant depth of about 1.3 microns into the semiconductor layer structure. Multiple ion implantation steps having different implant energies are used to form the p-type blocking junction 150B. As can be seen, the p-type blocking junctions 150B exhibit much higher levels of straggle. Moreover, the straggle is predominantly to the sides of the p-type blocking junctions 150B, meaning that the stray p-type ions are implanted throughout the conductive regions 155. Unfortunately, the implantation of stray p-type ions into the conductive regions 155 creates choke points (also called bottlenecks) that the current must flow around, which acts to concentrate the flow of electrons in the regions around the stray p-type ions. This tends to increase the on-state resistance of the Schottky diode 100B. In addition, the lower portion of each p-type blocking junction 150B is wider than the upper portion of the p-type blocking junction 150B. Thus, the conductive regions 155 end up being narrowest at the lower portion of the p-type blocking junction 150B. This may be undesirable, as current crowding also tends to occur in this region and hence the shape of the p-type blocking junction 150B may tend to increase the on-state resistance of the Schottky diode 100B of FIG. 4B.

FIG. 4C is a cross-sectional view of a small portion of a 4H silicon carbide based Schottky diode 100C that illustrates a pair of deep p-type blocking junctions 150C that are formed using channeled ion implantation techniques. The p-type blocking junctions 150C have an implant depth of about 1.3 microns. As can be seen, each p-type blocking junction 150C exhibits significantly less straggle than is present in the p-type blocking junctions 150B of FIG. 4B. Moreover, the straggle is predominantly above and below the “bulge” in the p-type blocking junction 150C where the p-type blocking junction 150C is the widest. Straggle in this location may have less of an impact on performance, since it not narrowing the width of the conductive region 155 where the conductive region is narrowest. In addition, it can be seen that the shape of each p-type blocking junction 150C is different than the shape of the p-type blocking junctions 150B. In particular, a central region of the p-type blocking junction 150C has the greatest width, while the lower portion of the p-type blocking junction 150C has a reduced width. As a result, the width of the conductive region 155 is larger adjacent the bottom corners of the p-type blocking junction 150C, where the current crowding effects occur. This may improve current flow in this region, reducing the on-state resistance of the Schottky diode 100C of FIG. 4C as compared to the Schottky diode 100B of FIG. 4B.

As discussed above, the power Schottky diode 100 includes a combination of deeper than normal blocking junctions 150, the use of channeled ion implantation techniques to form the blocking junctions 150, and the provision of a current spreading layer 145 that may extend at least to the lower corners of the blocking junctions 150. The deeper blocking junctions 150 may improve the reverse bias performance of the Schottky diode 100 by reducing the electric field strength in the conductive regions 155 during reverse bias operation, thereby reducing the leakage current levels for a given applied reverse bias voltage. The deeper blocking junctions 150, however, tend to increase the on-state resistance of the Schottky diode 100. To counteract this effect, the current spreading layer 145 is provided that increases the conductivity of the conductive regions 155 and which helps alleviate current crowding effects that tend to occur in the portions of the conductive regions 155 that are adjacent the lower corners of the blocking junctions 150. In addition, by forming the blocking junctions using a channeled ion implant, the amount of straggle into the conductive regions 155 may be significantly reduced, and may be almost eliminated near the bottom corners of the blocking junctions 150. This may be accomplished, for example, by forming the blocking junctions 150 through a series of channeled ion implants, where the ion implantation masks have different widths and/or the implants are performed at different implant energies. For example, a first ion implant that is used to form the blocking junctions 150 may have a higher implant energy and a mask with narrower openings. This implant may be used to form the central portion of each blocking junction 150 (as viewed in the cross-sectional view of FIG. 1B). A second ion implant is performed (either before or after the first implant) that has a lower implant energy and is performed using a mask with wider openings. This implant may be used to form the outer portions of each blocking junction 150 (as viewed in the cross-sectional view of FIG. 1B). The net result may be that the blocking junctions 150 have less straggle. This may improve the on-state resistance of the Schottky diode 100. Additionally, the use of such a multi-step ion implantation process may improve the shape of the blocking junctions 150 so that they provide improved on-state performance, as the width of the conductive region 155 at a depth corresponding to the bottoms of the blocking junctions 150 is increased. For example, the multi-width ion implantation process may be performed so that an average width of an upper half of each blocking junction 150 may exceed an average width of the lower half of the blocking junction 150. All told, these changes result in a Schottky diode 100 that may have improved performance as compared to conventional Schottky diodes (i.e., improved leakage current performance for similar on-state performance, improved on-state performance for similar leakage current performance, or improvements in both leakage current and on-state performance).

FIG. 1C illustrates an example doping profile along a vertical centerline of one of the p-type blocking junctions 150 of the power Schottky diode 100 of FIGS. 1A-1B. As shown in FIG. 1C, the blocking junction 150 may have a p-type dopant concentration of about 1×10¹⁹/cm³ to about 3×10²⁰/cm³ at the upper surface of the drift region 140, a p-type dopant concentration of about 1×10¹⁸/cm³ from a depth of about 0.3 microns to a depth of about 1.5 microns, and then rapidly decreasing concentrations at depths below 1.8 microns. For purposes of the present disclosure, the depth of the p-type blocking junction 150 is the depth at which the p-type blocking junction 150 has a doping concentration of at least 1×10¹⁷/cm³. In the example of FIG. 1C, the depth of the p-type blocking junction 150 is about 1.8 microns.

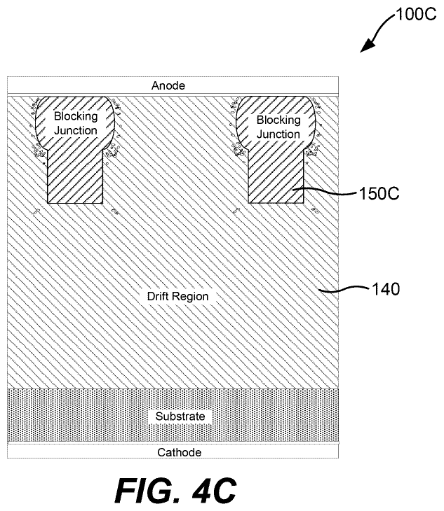

FIG. 5A is a schematic cross-sectional view of a power Schottky diode 200A according to further embodiments of the present invention. The Schottky diode 200A may be similar in many respects to the Schottky diode 100 that is discussed above. Thus, the discussion that follows will focus on the differences between the two Schottky diodes 100, 200A. Elements of Schottky diode 200A that may be identical to the corresponding elements of Schottky diode 100 are labelled using the same reference numerals used for Schottky diode 100 to emphasize that the description of these elements above with respect to Schottky diode 100 applies equally with respect to Schottky diode 200A. The same convention is used with the Schottky diodes according to additional embodiments of the present invention that are discussed below.

As can be seen by comparing FIG. 1B and FIG. 5A, the primary difference between Schottky diode 200A and Schottky diode 100 is that in Schottky diode 200A (1) the current spreading layer 245A extends a bit deeper into the semiconductor layer structure 200A than current spreading layer 145 extends into the semiconductor layer structure 100 and (2) the current spreading layer 245A is a graded current spreading layer. In the depicted embodiment, at least a portion of the current spreading layer 245A is graded to have an increasing n-type dopant concentration with increasing depth into the semiconductor layer structure 200A, as shown by the arrow 247. The current spreading layer 245A is a graded so that the doping concentration is highest at or near a depth into the semiconductor layer structure 230A that corresponds to the bottoms of the blocking junctions 150. As a result, the doping level in the portions of the conductive regions 155 that are adjacent the lower corners of the blocking junctions 150 is higher, thereby reducing current crowding effects in these regions. Moreover, since the doping concentration of the current spreading layer 245A is graded, the doping concentration of much of the current spreading layer 245A may be lower than the doping concentration of current spreading layer 145, and hence the current spreading layer 245A may have less of a negative impact on reverse leakage current performance.

While FIG. 5A illustrates the current spreading layer 245A having a depth into the semiconductor layer structure 230A that extends below the bottoms of the blocking junctions 150, it will be appreciated that embodiments of the present invention are not limited thereto. For example, in other embodiments, the current spreading layer 245A may have a depth that is about the same as (i.e., within +/−5%) the depth of the blocking junctions or may even have a depth that is less than a depth of the blocking junctions 150, although preferably the depth of the blocking junctions 150 is not more than 25% deeper than the depth of the current spreading layer 245A. The full advantage of the current spreading layer is realized if the current spreading layer extends at least as deep into the semiconductor layer structure as the blocking junctions.

It will also be appreciated that more complex grading schemes may be used. For example, as shown in FIG. 5B, a Schottky diode 200B that is a modified version of Schottky diode 200A that has a current spreading layer 245B that has a different grading profile than current spreading layer 245A of Schottky diode 200A. As shown in FIG. 5B, an upper portion of the current spreading layer 245B may be graded to have an increasing n-type dopant concentration with increasing depth into the semiconductor layer structure 230B until a peak doping concentration is reached at a depth D1, and the lower portion of the current spreading layer 245B (i.e., the portion extending downwardly from depth D1) may be graded to have a decreasing n-type dopant concentration with increasing depth into the semiconductor layer structure 230B. The grading profile of the current spreading layer 245B in Schottky diode 200B may again result in a maximum doping concentration of the current spreading layer 245B may occur at a depth that is about the same as the depth of the bottoms of the blocking junctions 150, so that current crowding effects in the portions of the conductive regions 155 that are adjacent the lower corners of the blocking junctions 150 may be advantageously reduced.

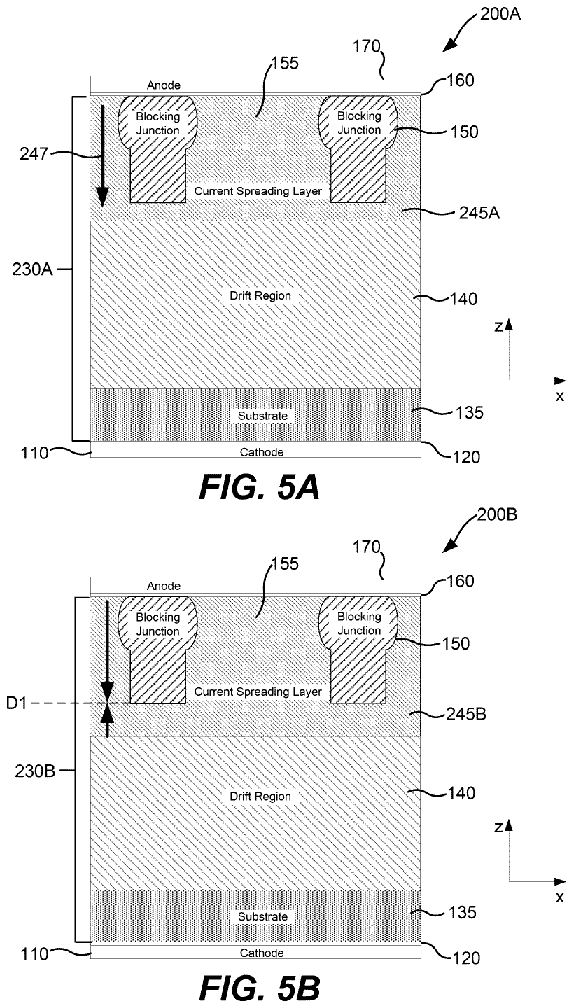

FIG. 6 is a schematic cross-sectional view of a power Schottky diode 300 according to further embodiments of the present invention. The Schottky diode 300 is similar to the Schottky diode 100 that is discussed above, except that Schottky diode 300 includes a buried current spreading layer 345.

Since the current spreading layer 345 is a buried current spreading layer 345, it acts to divide the drift region 340 into a lower drift region 342 and an upper drift region 344 that are separated by the current spreading layer 345. This allows the upper portion of the semiconductor layer structure 330 to have a lower doping concentration, which improves the reverse leakage current performance of Schottky diode 300. The lower drift region 342 and the upper drift region 344 may have the same n-type dopant concentrations or different n-type dopant concentrations. For example, in some cases the lower drift region 342 may have a higher n-type dopant concentration than the upper drift region 344, while in other cases the lower drift region 342 may have the same n-type dopant concentration or a lower n-type dopant concentration than the upper drift region 344. In the depicted embodiment, the current spreading layer 345 extends further into the semiconductor layer structure 330 than do the blocking junctions 150. It will be appreciated, however, that embodiments of the present invention are not limited thereto. For example, in other embodiments, the bottom of current spreading layer 345 may be about coplanar with the bottoms of the blocking junctions 150 or may even be at a shallower depth into the semiconductor layer structure 300 than the bottoms of the blocking junctions 150. The current spreading layer 345 may be formed during epitaxial growth or via ion implantation. The current spreading layer 345 may improve current flow in the vicinity of the lower corners of the blocking junctions 150.

It will be appreciated that various modifications may be made to the Schottky diode 300. For example, in other embodiments, the buried current spreading layer 345 may be a graded current spreading layer having, for example, any of the grading profiles discussed above with respect to Schottky diodes 200A and 200B.

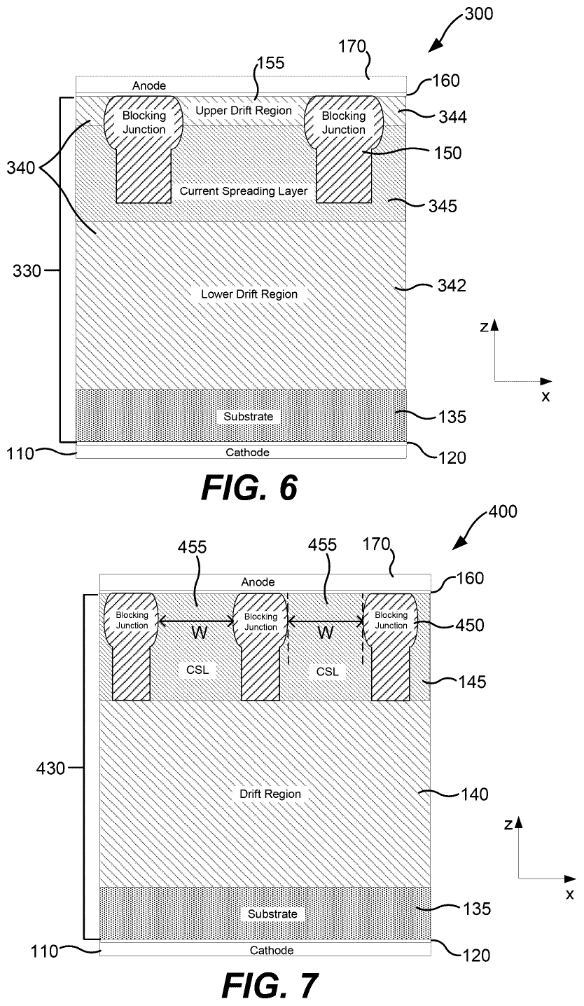

FIG. 7 is a schematic cross-sectional view of a power Schottky diode 400 according to further embodiments of the present invention. The Schottky diode 400 is similar to the Schottky diode 100 that is discussed above, except that Schottky diode 400 includes a greater number of blocking junctions 450 as compared to the number of blocking junctions 150 in Schottky diode 100 and (2) has narrower conductive regions 455 as compared to the conductive regions 155 in Schottky diode 100.

The current carrying capacity of a Schottky diode is a function of, among other things, the area of the total Schottky opening of the device, where the area of total Schottky opening is the sum of the areas of the individual Schottky openings formed between adjacent blocking junctions (i.e., the areas of the individual conductive regions). The area of each individual Schottky opening is determined as the minimum width (x-direction) of the individual Schottky opening multiplied by the length (y-direction) of the individual Schottky opening. In addition, the effectiveness of the blocking junctions of a Schottky diode depends on several factors including (1) the doping concentration of the conductive region, (2) the widths (and particularly the minimum widths) of the individual Schottky openings and (3) the depths of the blocking junctions. Increases in any of the above parameters (versus a baseline) acts to decrease the effectiveness of the blocking junctions in shielding the electric fields during reverse blocking operation.

The Schottky diode 400 has narrower conductive regions 455 (i.e., individual Schottky openings having reduced widths) as compared to the Schottky diodes 100, 200A, 200B and 300 that are discussed above. The narrower conductive regions 455 act to improve the effectiveness of the blocking junctions 450 in blocking the electric fields during reverse bias operations, thereby improving the reverse leakage current performance. Moreover, in order to maintain the total Schottky opening, the width of each blocking junction 450 is reduced as compared to the blocking junctions 150 of Schottky diodes 100, 200 and 300. In an example embodiment, the width of each conductive region 455 may be halved and the width of each blocking junction 450 may similarly be halved to maintain the total Schottky opening at a constant level. The width of each blocking junction 450 may be less than 1.0 microns in some embodiments. While the above technique may significantly improve the reverse bias performance, the doubling (or other increase) in the number of blocking junctions 450 increases (here doubles) the number of lower shield corners where current crowding occurs. However, as discussed above with reference to Schottky didoes 100, 200 and 300, various techniques are provided herein that may alleviate such current crowding.

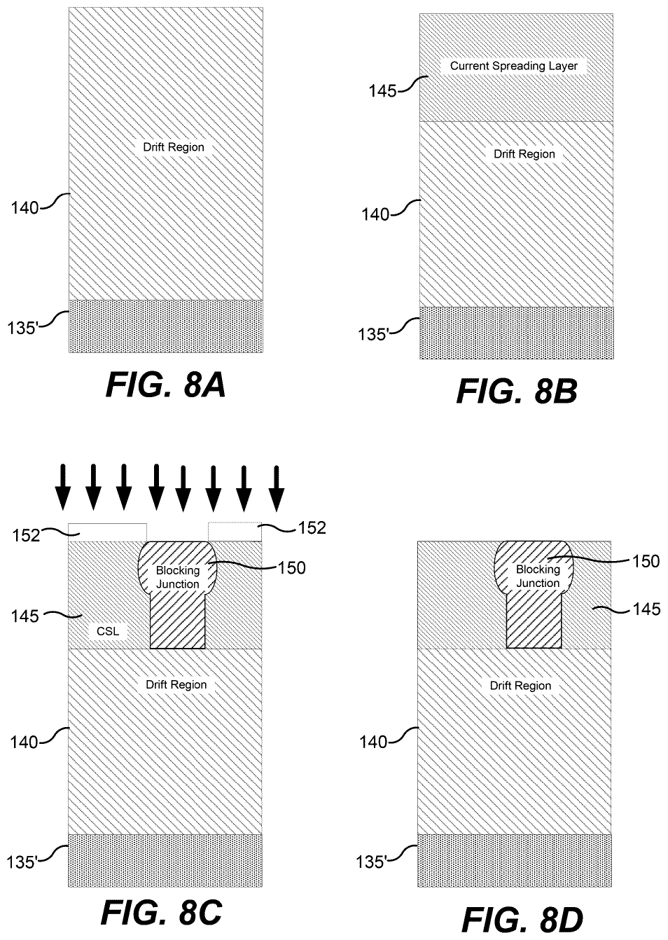

FIGS. 8A-8E are schematic cross-sectional diagrams that illustrate a method of fabricating the power Schottky diode 100 of FIGS. 1A-1B. It will be appreciated that the cross-sections of FIGS. 8A-8E only show a small portion of one Schottky diode 100 that is part of a silicon carbide wafer that includes a plurality of Schottky diodes 100.

As shown in FIG. 8A, the n-type drift region 140 is epitaxially grown on a silicon carbide wafer 135′ that will eventually be diced to convert the wafer 135′ into a plurality of substrates 135, where each substrate is part of an individual power Schottky diode 100. In some embodiments, the drift region 140 may be doped during growth with n-type impurities. The drift region 140 and the wafer 135′ both comprise at least part of a semiconductor layer structure 130.

As shown in FIG. 8B, an n-type current spreading layer 145 is formed in an upper portion of the semiconductor layer structure 130. In the depicted embodiment, the current spreading layer 145 is formed by ion implantation. In particular, n-type dopants are implanted into an upper portion of the drift region 140 to convert the upper portion of the drift region 140 into the current spreading layer 145. The current spreading layer 145 may have a maximum n-type dopant concentration that is, for example, between 1.5 and 4.0 times the maximum n-type dopant concentration of the drift region 140. While FIG. 8B illustrates an embodiment in which the current spreading layer 145 is formed via ion implantation, it will be appreciated that embodiments of the present invention are not limited thereto. For example, in other embodiments, the current spreading layer 145 may be formed via epitaxial growth on top of the drift region 140 by increasing the n-type dopant concentration that is supplied in the epitaxial growth process. In the illustrated embodiment, the current spreading layer 145 extends to the top of the semiconductor layer structure 130 and has a constant doping profile of n-type dopants, consistent with FIGS. 1A-1B. It will be appreciated that in other embodiments the current spreading layer 145 may have a graded doping profile as shown in FIGS. 5A-5B and/or may be implemented as a buried current spreading layer 145 as shown in FIG. 6.

Referring to FIG. 8C, next, an ion implantation mask layer (not shown) may be formed on the drift region 140, and this mask layer may then be patterned via, for example, conventional photolithography processing steps to form an ion implantation mask pattern 152. Subsequently, p-type dopants may be implanted into the upper portions of the n-type current spreading layer 145 that are exposed by the ion implantation mask pattern 152 in order to form the p-type blocking junctions 150. The p-type blocking junctions 150 may be highly doped with p-type dopants (e.g., to a concentration of 1×10¹⁸/cm³ or more). The blocking junctions 150 may have a depth of, for example, about 1.0-2.0 microns in some embodiments. The blocking junctions 150 may be formed using a channeled ion implant in some embodiments.

In the depicted embodiment, the blocking junctions 150 and the current spreading layer 145 each extend to about the same depth into the semiconductor layer structure 130. It will be appreciated that in other embodiments the blocking junctions 150 may extend farther into the semiconductor layer structure 130 than does the current spreading layer 145 or the current spreading layer 145 may extend farther into the semiconductor layer structure 130 than do the blocking junctions 150.

Referring to FIG. 8D, the ion implantation mask pattern 152 may then be removed. Finally, as shown in FIG. 8E, the ohmic contact layer 120, the cathode contact 110, the Schottky contact 160 and the anode contact 170 may be formed to complete the power Schottky diode 100.

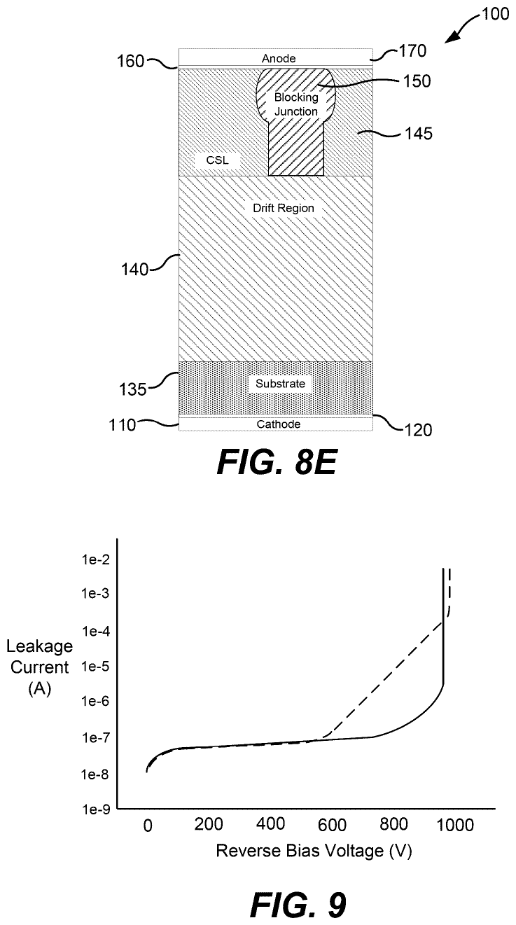

FIG. 9 is a graph that compares the reverse leakage current performance of a conventional power Schottky diode (the dashed curve) to a power Schottky diode according to embodiments of the present invention (the solid curve). As shown in FIG. 9, both power Schottky diodes exhibit similar performance at reverse bias voltages below about 600 V. At reverse bias voltages starting at about 600 V the leakage current in the conventional power Schottky diode starts to increase significantly (and generally) linearly until at a reverse blocking voltage of about 1000 V avalanche breakdown occurs. In contrast, at reverse bias voltages starting at about 600 V the leakage current in the power Schottky diode according to embodiments of the present invention increases much more gradually until at a reverse blocking voltage of about 1000 V avalanche breakdown occurs. As a result, for a given reverse bias voltage rating above 600 V the power Schottky diode according to embodiments of the present invention will exhibit reduced reverse leakage currents as compared to the conventional power Schottky diode.

While the above embodiments of the present invention have primarily been discussed with reference to silicon carbide devices, it will be appreciated that the above techniques may also be used on other types of power Schottky diodes including power Schottky diodes fabricated in gallium nitride based materials.

While in the description above, the example embodiments are described with respect to semiconductor devices that have n-type substrates and conductive regions in n-type portions of the drift regions, it will be appreciated that opposite conductivity type devices may be formed by simply reversing the conductivity of the n-type and p-type regions in each of the above embodiments. Thus, it will be appreciated that the present invention covers both n-type and p-type devices. Accordingly, the claims appended hereto refer to the first and second conductivity type dopants as opposed to n-type and p-type dopants.

Herein, embodiments of the present invention are typically described with respect to cross-sectional diagrams that only illustrate one or two unit cells of a power Schottky diode. It will be appreciated that some implementations will include a larger number of unit cells. However, it will also be appreciated that the present invention is not limited to such devices, and that the claims appended hereto also cover power Schottky diodes that comprise a single unit cell.

The vertical power Schottky diodes according to embodiments of the present invention have a drift region that extends vertically between cathode and anode contacts. In such devices, the lateral direction refers to the horizontal direction. Thus, the lateral width of a conductive region refers to the horizontal width of the conductive region and may be measured as the distance between sidewalls of adjacent blocking junctions.

Embodiments of the present invention have been described above with reference to the accompanying drawings, in which embodiments of the invention are shown. It will be appreciated, however, that this invention may, however, be embodied in many different forms and should not be construed as limited to the embodiments set forth above. Rather, these embodiments are provided so that this disclosure will be thorough and complete, and will fully convey the scope of the invention to those skilled in the art. Like numbers refer to like elements throughout.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the present invention. The term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising.” “includes” and/or “including” when used herein, specify the presence of stated features, operations, elements, and/or components, but do not preclude the presence or addition of one or more other features, operations, elements, components, and/or groups thereof.

Relative terms such as “below” or “above” or “upper” or “lower” and the like may be used herein to describe a relationship of one element, layer or region to another element, layer or region as illustrated in the figures. It will be understood that these terms are intended to encompass different orientations of the device in addition to the orientation depicted in the figures.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Embodiments of the invention are described herein with reference to plan and cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected.

In the drawings and specification, there have been disclosed typical embodiments of the invention and, although specific terms are employed, they are used in a generic and descriptive sense only and not for purposes of limitation, the scope of the invention being set forth in the following claims.

1. A Schottky diode, comprising:
a first contact;
a second contact; and
a semiconductor layer structure between the first contact and the second contact, the semiconductor layer structure comprising:
a current spreading layer having a first conductivity type;
a drift region between the second contact and the current spreading layer, the drift region having the first conductivity type; and
a first blocking junction having a second conductivity type that is opposite the first conductivity type, the first blocking junction extending downwardly from an upper surface of the semiconductor layer structure,
wherein the current spreading layer has a first conductivity type dopant concentration that is at least 1.5 times greater than a first conductivity type dopant concentration of the drift region, and
wherein the current spreading layer vertically overlaps at least a portion of a lower half of the first blocking junction.

2. (canceled)

3. The Schottky diode of claim 12, further comprising a second blocking junction that is doped with dopants having the second conductivity type, the second blocking junction extending downwardly from the upper surface of the semiconductor layer structure, where the first and second blocking junctions extend to a depth of between 1.0 and 2.0 microns into the semiconductor layer structure.

4-6. (canceled)

7. The Schottky diode of claim 12, wherein the first blocking junction is a channel implanted blocking junction.

8. The Schottky diode of claim 1, wherein the current spreading layer extends farther downwardly into the semiconductor layer structure than does the first blocking junction.

9-11. (canceled)

12. The Schottky diode of claim 1, wherein a bottom of the current spreading layer extends at least as deep into the semiconductor layer structure as a bottom of the first blocking junction, and a doping concentration of the current spreading layer at a depth into the semiconductor layer structure that is the same depth as the bottom of the first blocking junction is at least 1×10¹⁷/cm³.

13. The Schottky diode of claim 1, wherein at least a first portion of the current spreading layer has a graded doping concentration of first conductivity type dopants, where in the first portion the doping concentration of first conductivity type dopants increases with increasing depth into the semiconductor layer structure.

14. The Schottky diode of claim 13, wherein the maximum doping concentration of the current spreading layer is at a depth from the upper surface of the semiconductor layer structure that is within 0.2 microns of a depth of a bottom of the first blocking junction.

15. The Schottky diode of claim 1, wherein the current spreading layer is a buried current spreading layer and the drift region is a lower drift region, the semiconductor layer structure further comprising an upper drift region that is between the current spreading layer and the first contact.

16-17. (canceled)

18. A Schottky diode, comprising:
a first contact that has at least a first portion that is a Schottky contact;
a second contact; and
a semiconductor layer structure between the first contact and the second contact, the semiconductor layer structure comprising:
a drift region having a first conductivity type;
a current spreading layer between at least a portion of the drift region and the first contact, the current spreading layer having the first conductivity type, where a first conductivity type dopant concentration of the current spreading layer is higher than the first conductivity type dopant concentration of the drift region; and
a first blocking junction adjacent the first contact, the first blocking junction having a second conductivity type that is opposite the first conductivity type, wherein a first portion of the current spreading layer has a graded dopant concentration that increases with increasing distance from the first contact.

19. The Schottky diode of claim 18, wherein the current spreading layer further comprises a second portion that has a graded dopant concentration that decreases with increasing distance from the first contact.

20. The Schottky diode of claim 18, wherein the current spreading layer further includes a second portion that has a substantially constant dopant concentration with increasing distance from the first contact.

21. The Schottky diode of claim 18, the semiconductor layer structure further comprising a second blocking junction adjacent the first contact that is doped with dopants having the second conductivity type, where the first and second blocking junctions extend to a depth of between 1.0 and 2.0 microns into the semiconductor layer structure from the first contact.

22. The Schottky diode of claim 21, wherein the first and second blocking junctions are spaced apart from each other by less than 1.0 micron.

23. The Schottky diode of claim 22, wherein a maximum width of the first blocking junction is less than 1.0 microns.

24. (canceled)

25. The Schottky diode of claim 18, wherein a minimum distance between the current spreading layer and the second contact is less than a minimum distance between the first blocking junction and the second contact.

26. (canceled)

27. The Schottky diode of claim 18, wherein the current spreading layer is a buried current spreading layer and the drift region is a lower drift region, the semiconductor layer structure comprises an upper drift region that is between the current spreading layer and the first contact.

28. A Schottky diode, comprising:
a semiconductor layer structure comprising:
a lower drift region having a first conductivity type;
an upper drift region having the first conductivity type;
a current spreading layer having the first conductivity type between the lower drift region and the upper drift region, where a first conductivity type dopant concentration of the current spreading layer is higher than a first conductivity type dopant concentration of the lower drift region and is higher than a first conductivity type dopant concentration of the upper drift region;
a first blocking junction having a second conductivity type that is opposite the first conductivity type; and
a second blocking junction having the second conductivity type,
wherein the first and second blocking junctions define a conductive region therebetween.

29-30. (canceled)

31. The Schottky diode of claim 28, wherein the first contact is adjacent top surfaces of the first and second blocking junctions and bottom surfaces of the first and second blocking junctions are between 1.0 and 2.0 microns from an upper surface of the semiconductor layer structure.

32. The Schottky diode of claim 31, wherein a bottom surface of the current spreading layer is farther from the first contact than are bottom surfaces of the first and second blocking junctions.

33-63. (canceled)

64. The Schottky diode of claim 1, wherein a maximum width of an upper half of the first blocking junction exceeds a maximum width of a lower half of the first blocking junction.

65. The Schottky diode of claim 18, wherein a maximum width of an upper half of the first blocking junction exceeds a maximum width of a lower half of the first blocking junction.
